(19) United States
(12) Patent Application Publication
(10) Pub. No.: US 2026/0032910 A1
(43) Pub. Date: Jan. 29, 2026

(54) Integrated Circuitry And Methods Used In Forming Integrated Circuitry

(71) Applicant: Micron Technology, Inc., Boise, ID (US)

(72) Inventors: Darwin A. Clampitt, Wilder, ID (US); M. Jared Barclay, Middleton, ID (US); Collin Howder, Boise, ID (US)

(73) Assignee: Micron Technology, Inc., Boise, ID (US)

(21) Appl. No.: 19/235,323

(22) Filed: Jun. 11, 2025

Related U.S. Application Data
(60) Provisional application No. 63/675,509, filed on Jul. 25, 2024.

(51) Int. Cl. H10B 43/27; H01L 23/522; H01L 23/528; H10B 41/10; H10B 41/27; H10B 41/35; H10B 43/10; H10B 43/35

(52) U.S. Cl. CPC H10B 43/27; H01L 23/5226; H01L 23/528; H01L 23/5283; H10B 41/10; H10B 41/27; H10B 41/35; H10B 43/10; H10B 43/35

(57) ABSTRACT

Integrated circuitry comprises a stack comprising vertically-alternating insulative tiers and conductive tiers that extend from an array region into a stair-step region. The stair-step region comprises a flight of stairs that comprise treads that individually comprise a target conductive tier. A conductive via extends from directly above, through, and to directly below one of the individual treads to a bottom of the stack. It comprises conductor material that is directly electrically coupled to conductive material that is in the target conductive tier of the one individual tread. The conductive material that is in the target conductive tier of the one individual tread extends upwardly and downwardly from the target conductive tier of the one individual tread and is aside and directly against sidewalls of the conductor material of the conductive via directly above and directly below the target conductive tier of the one individual tread. Other embodiments, including method, are disclosed.

### TECHNICAL FIELD

Embodiments disclosed herein pertain to integrated circuitry and to methods used in forming integrated circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

Flash memory is one type of memory and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

Memory arrays may be arranged in memory pages, memory blocks and partial blocks (e.g., sub-blocks), and memory planes, for example as shown and described in any of U.S. Patent Application Publication Nos. 2015/0228651, 2016/0267984, and 2017/0140833. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

Integrated circuitry other than memory circuitry may also comprise a stack comprising vertically-alternating insulative tiers and conductive tiers that extend from an array region into a stair-step region, with the array region comprising an array of electronic components.

### BRIEF DESCRIPTION OF THE DRAWINGS

FIG. 1 is a diagrammatic view of a portion of memory circuitry in process in accordance with embodiments of the invention.

FIG. 3 is a diagrammatic cross-sectional view taken through line 3-3 in FIG. 1.

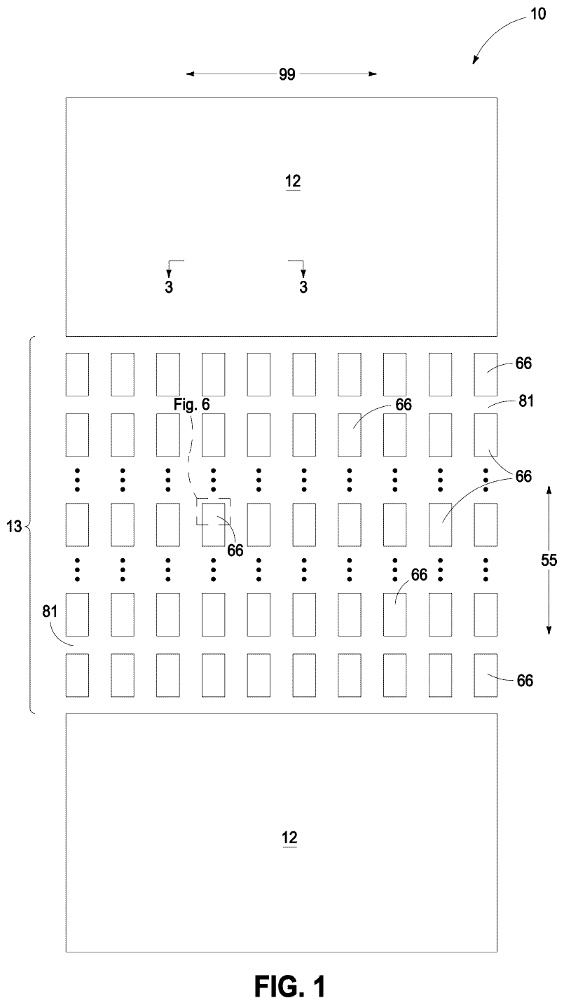

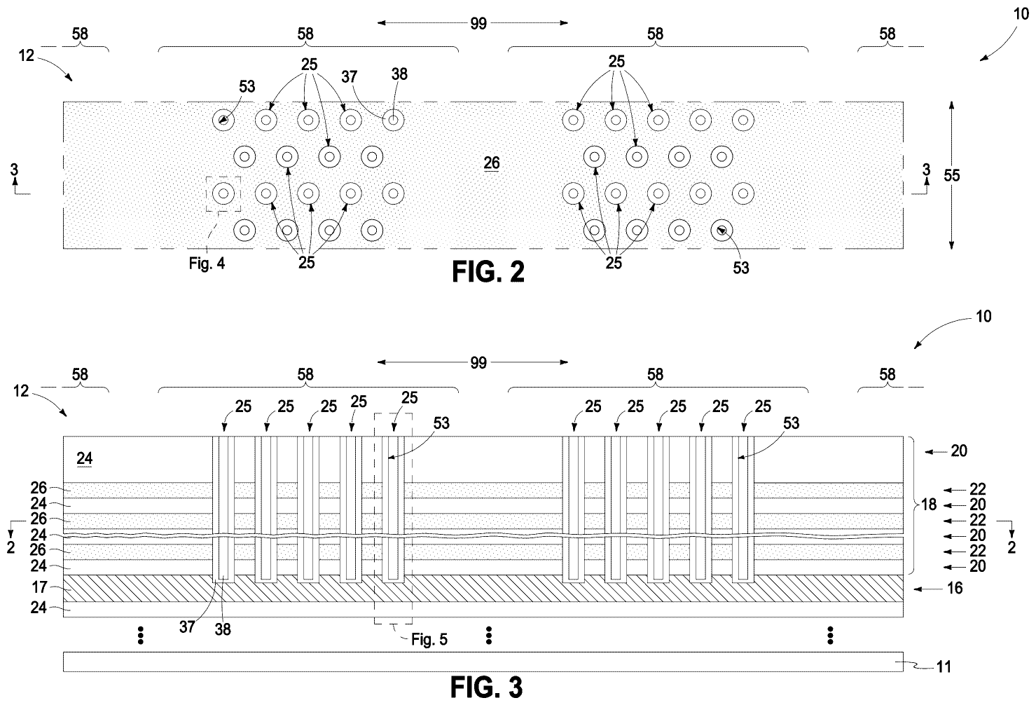

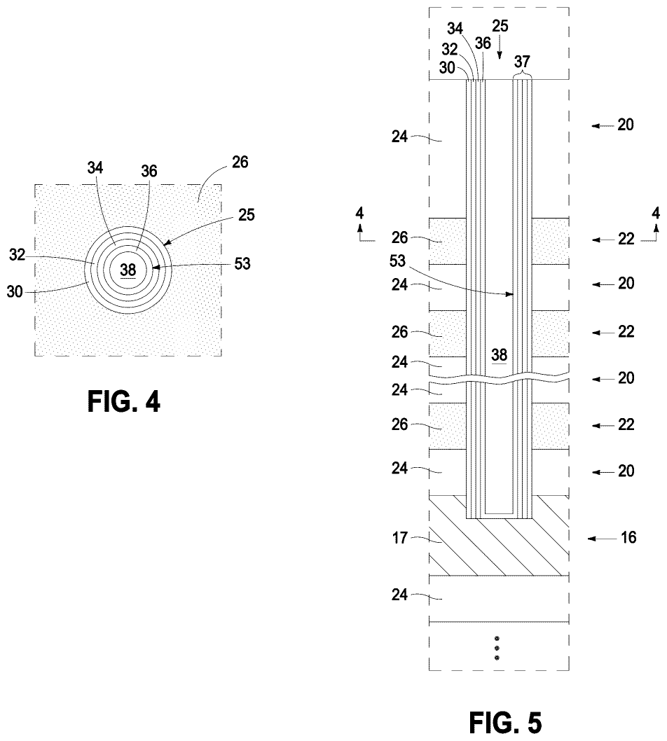

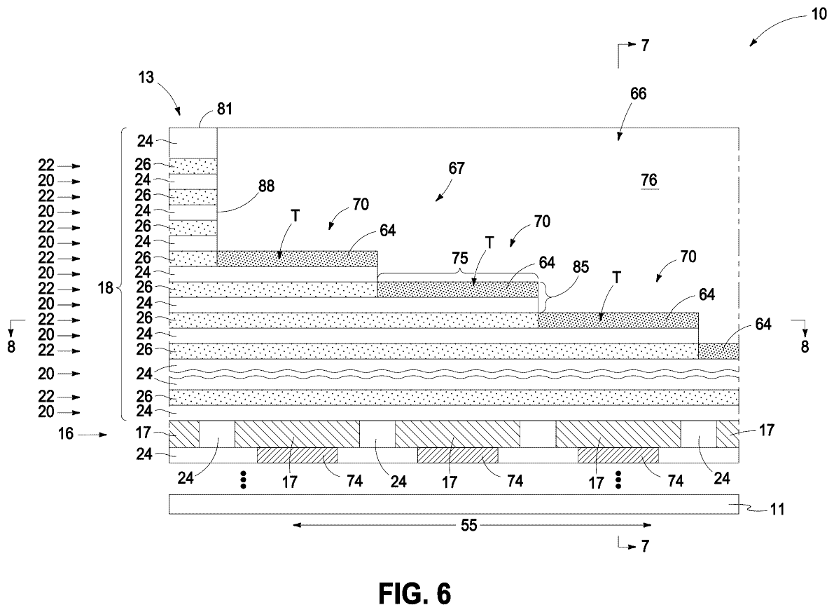

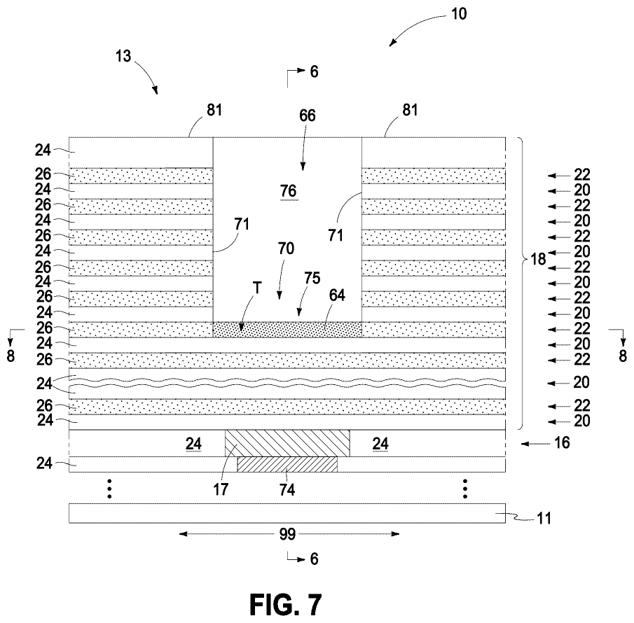

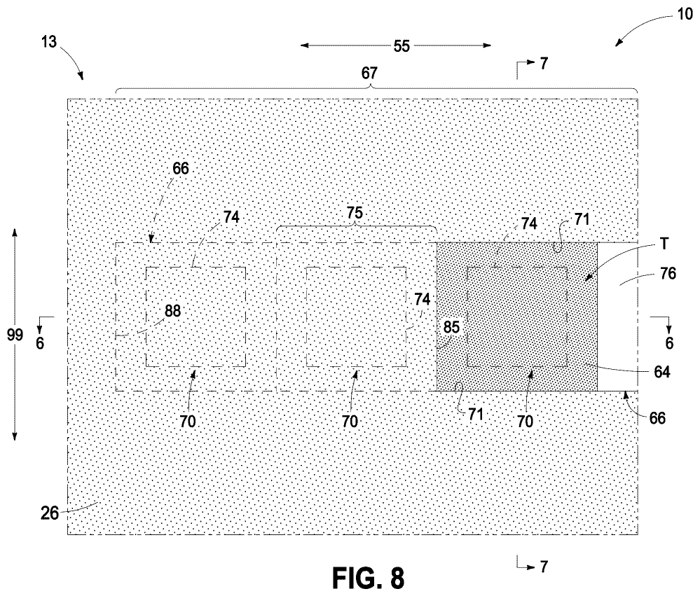

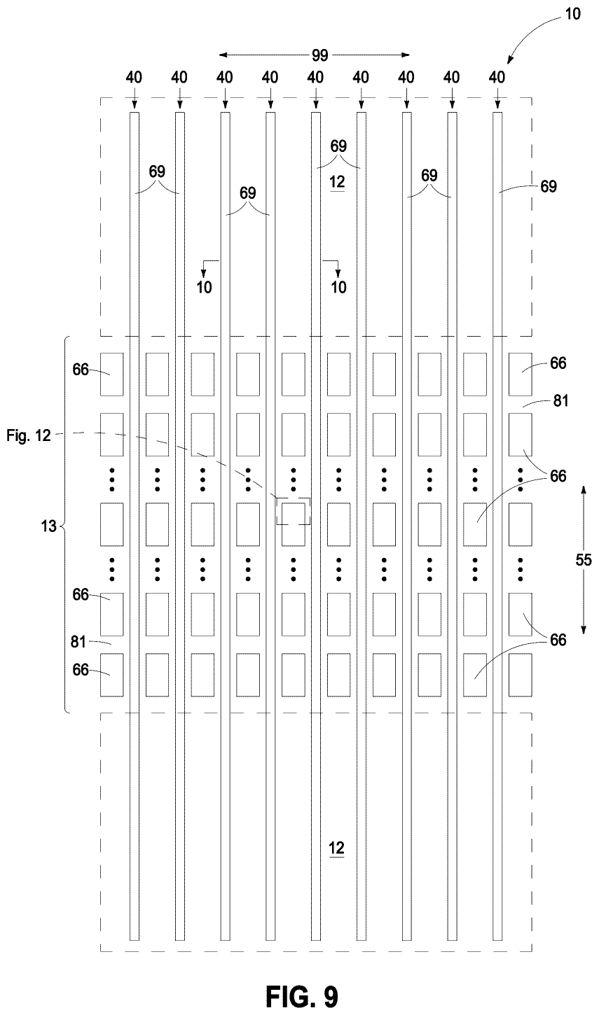

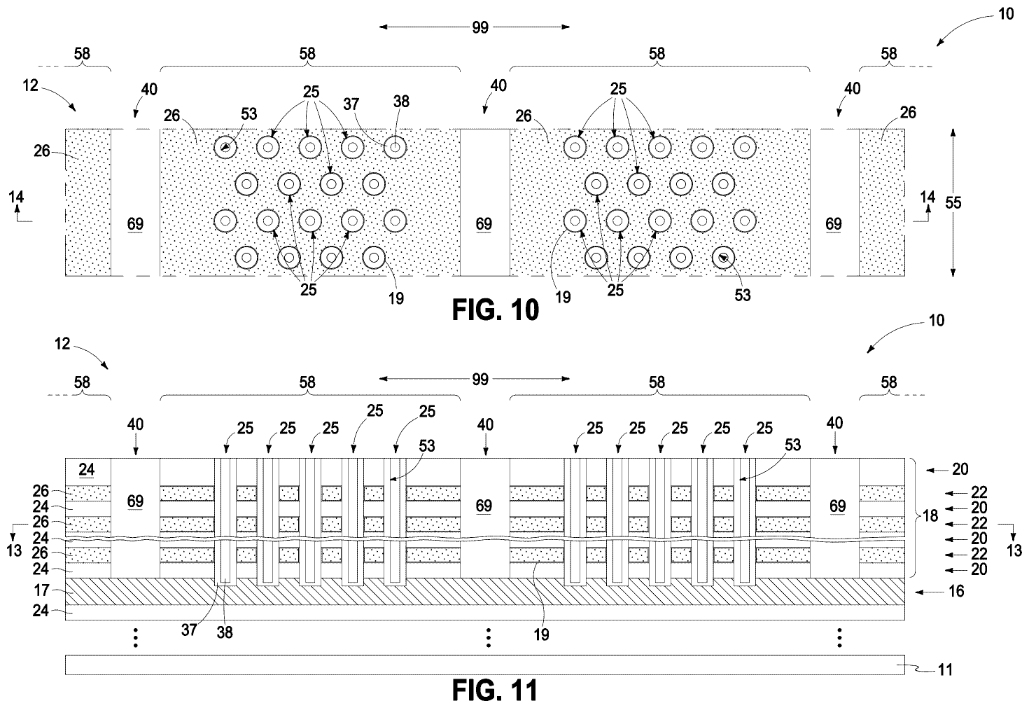

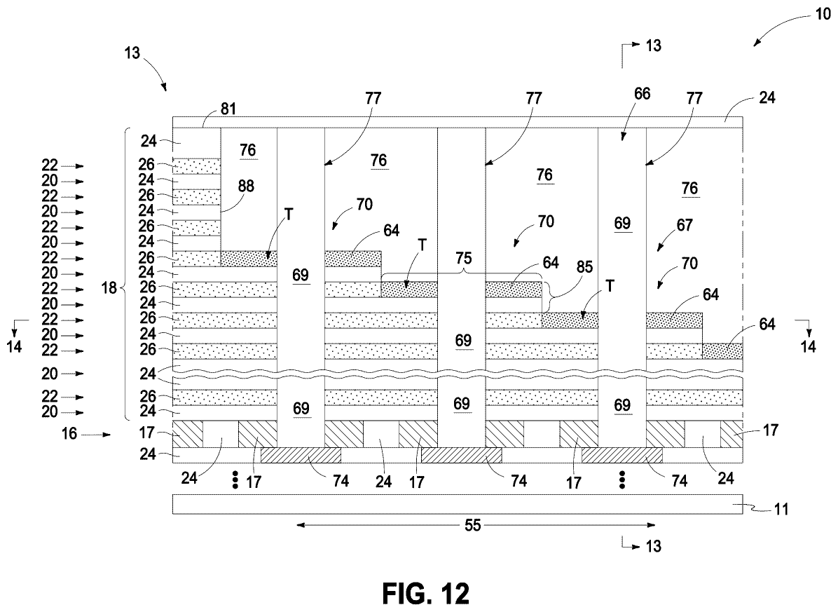

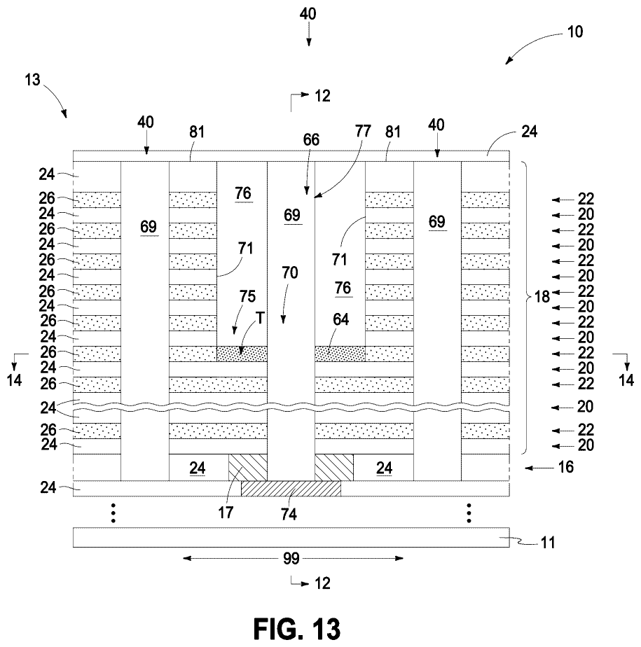

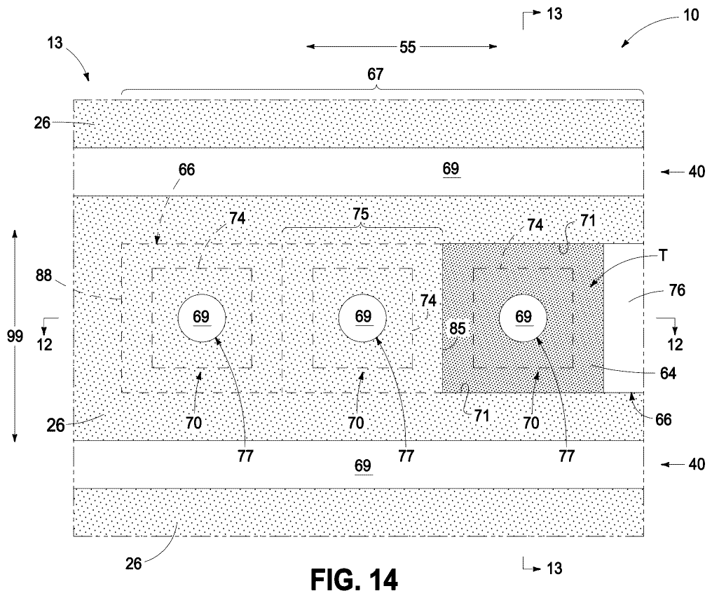

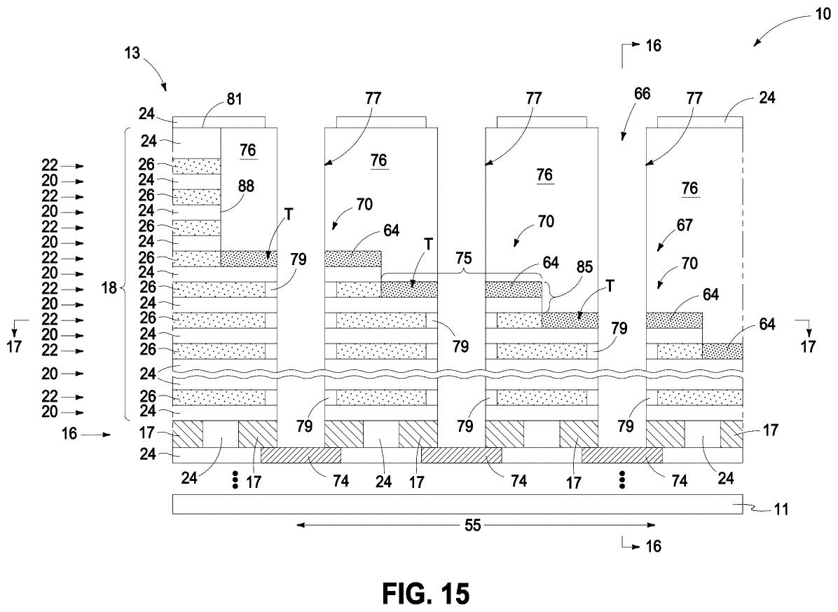

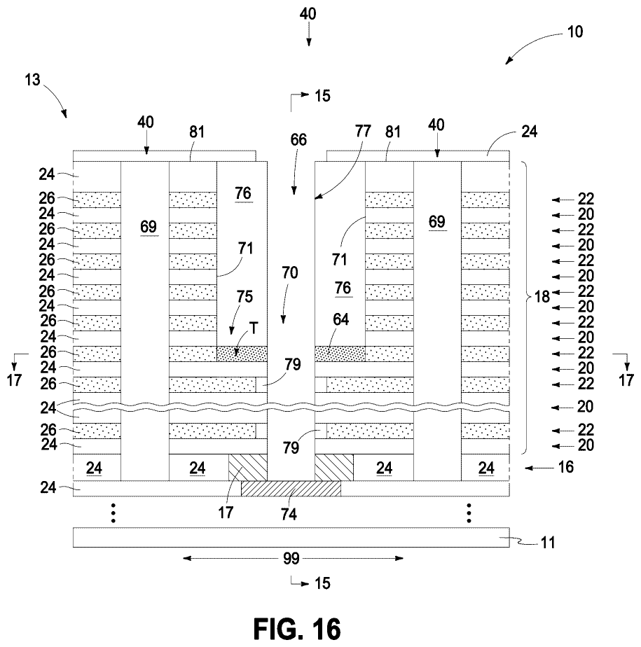

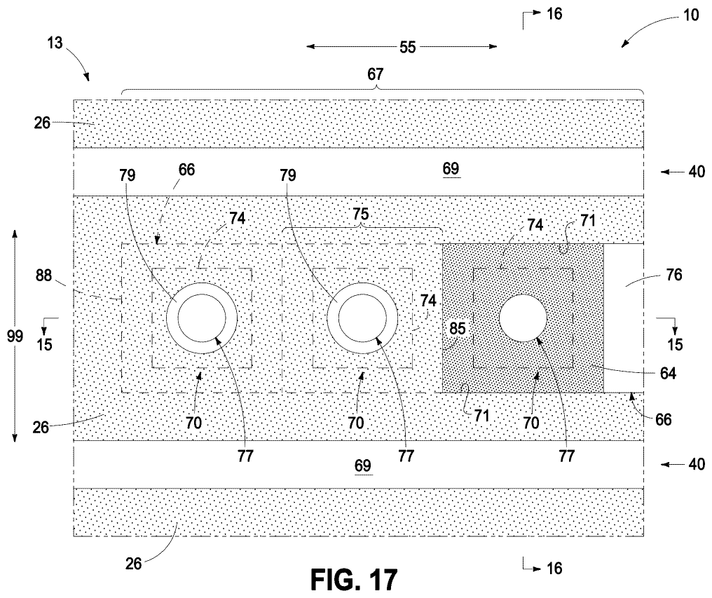

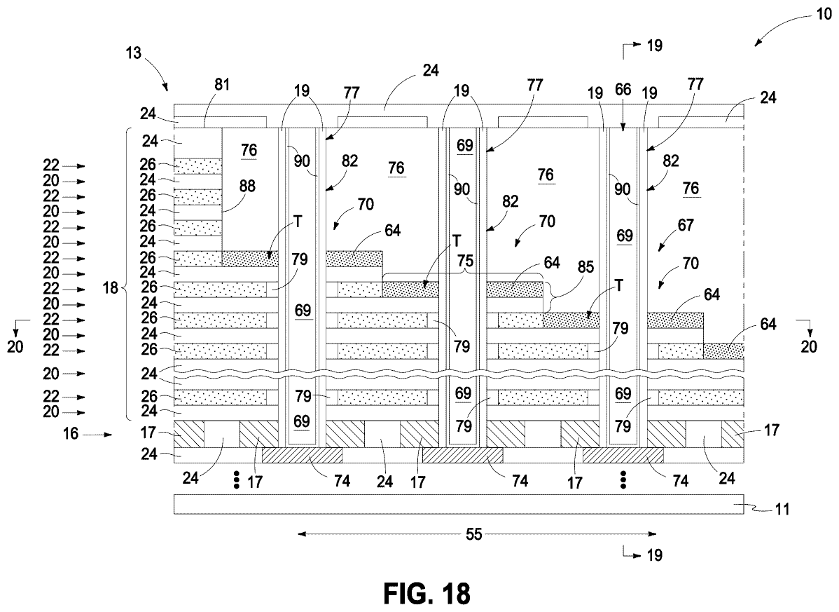

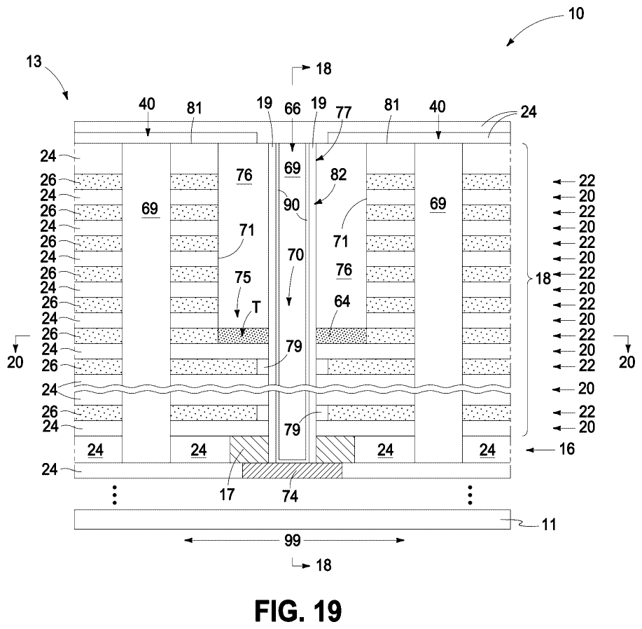

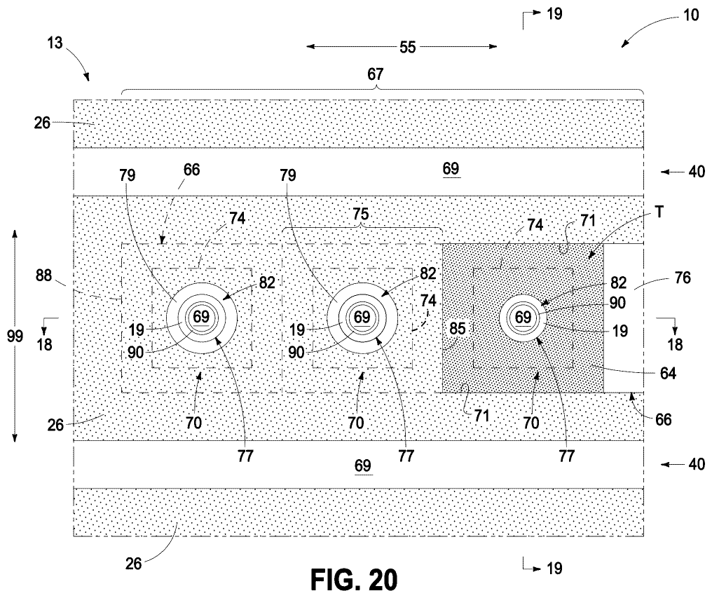

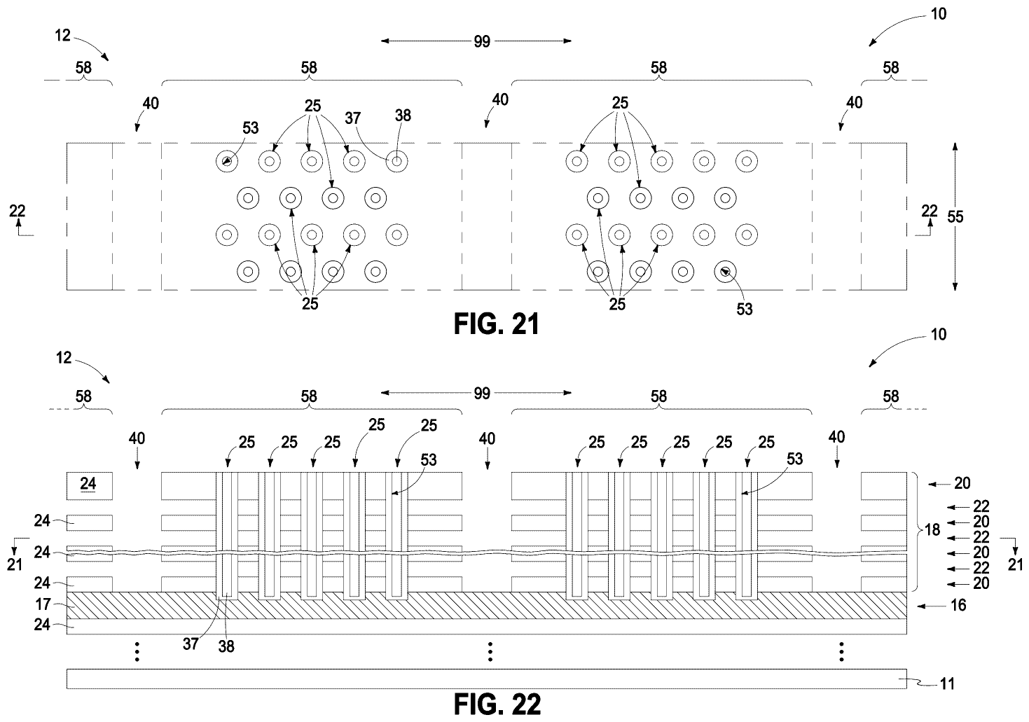

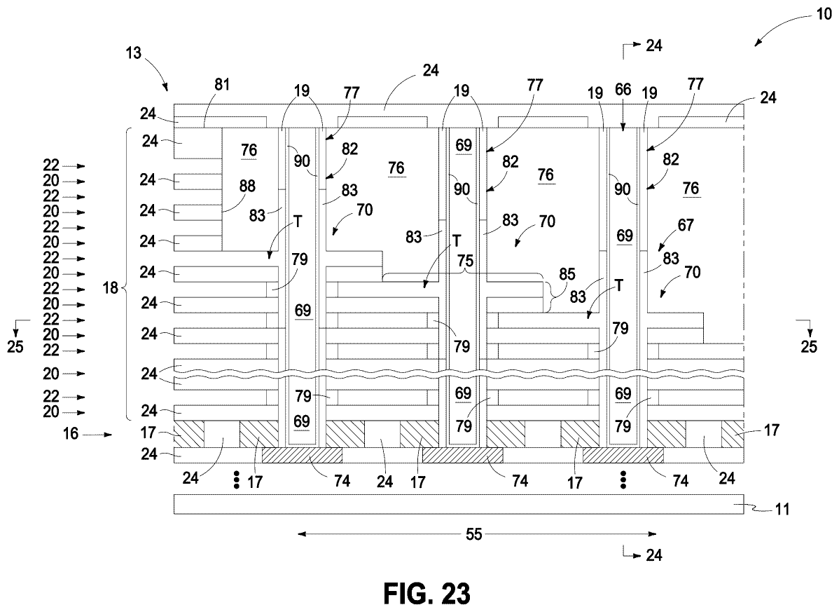

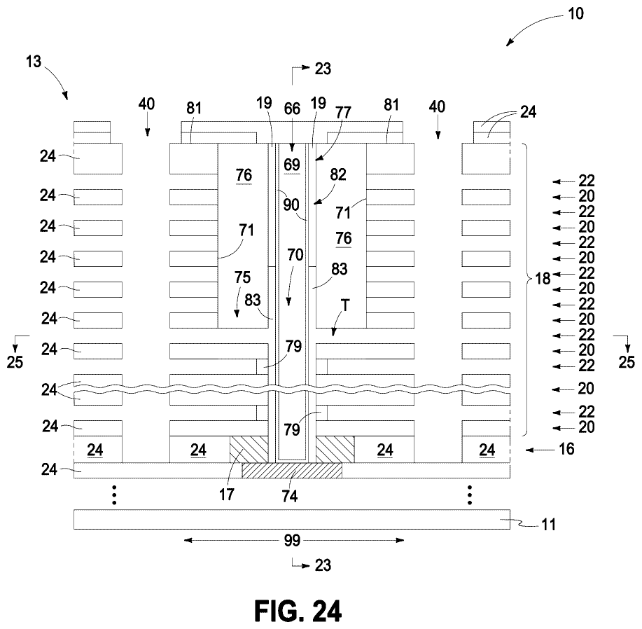

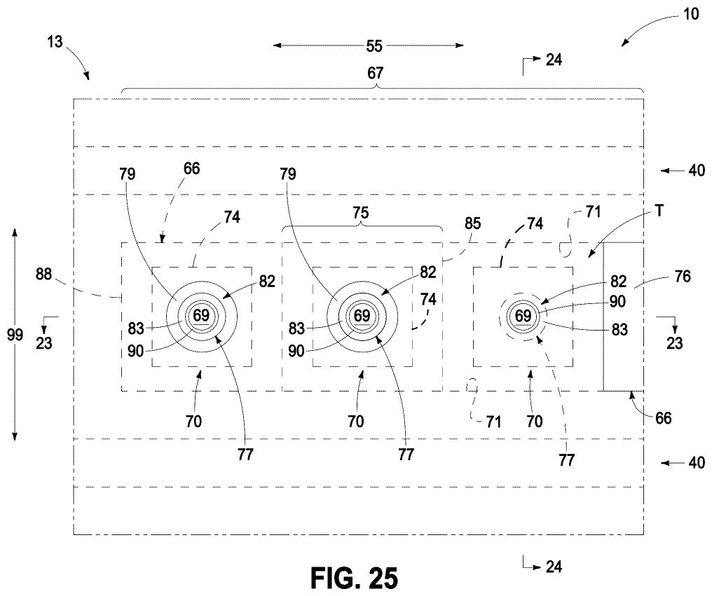

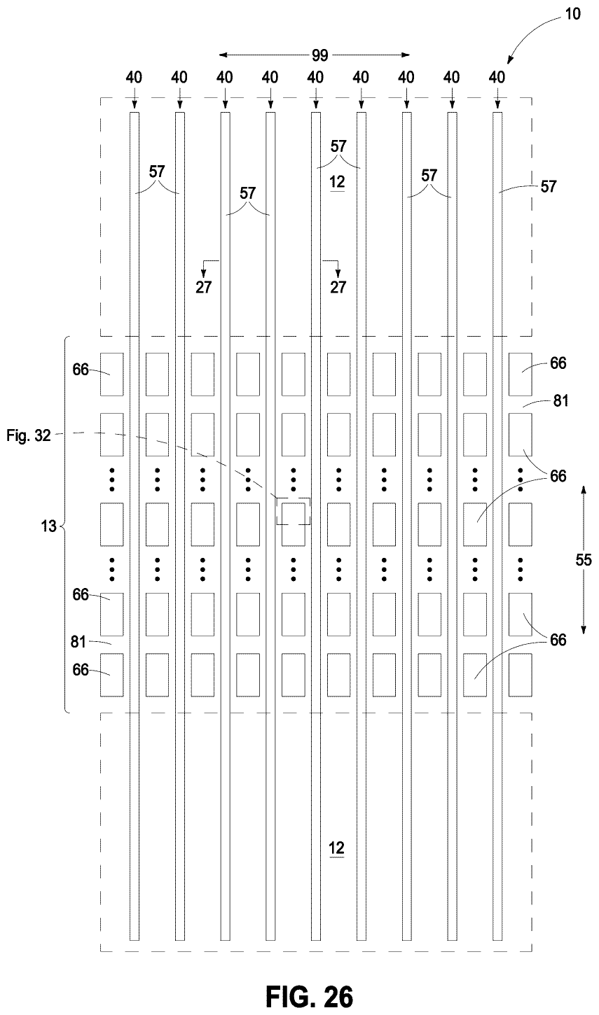

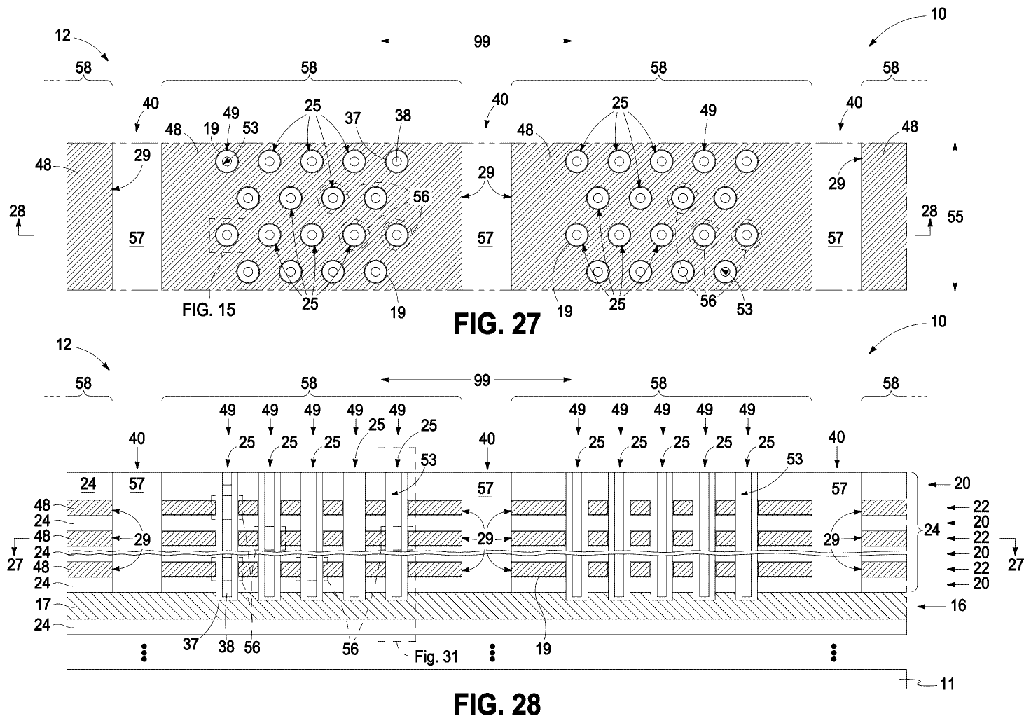

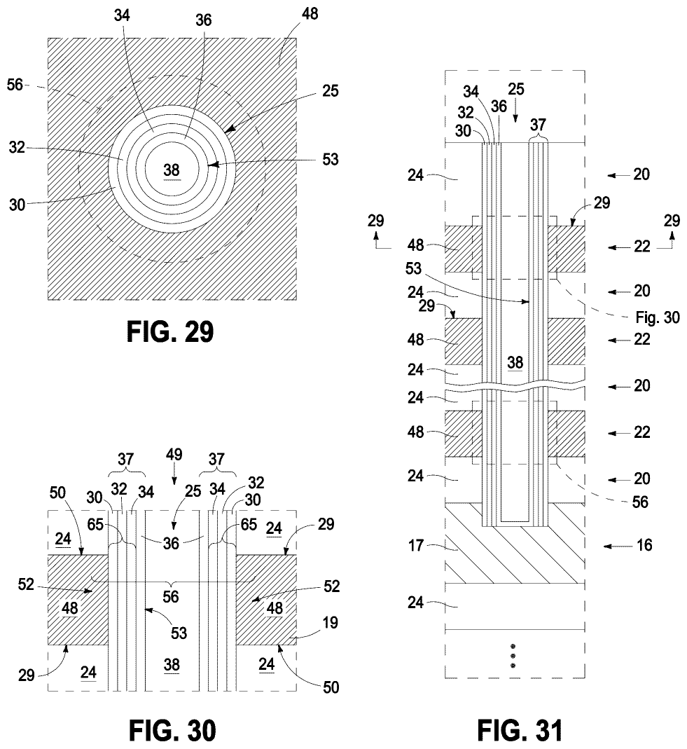

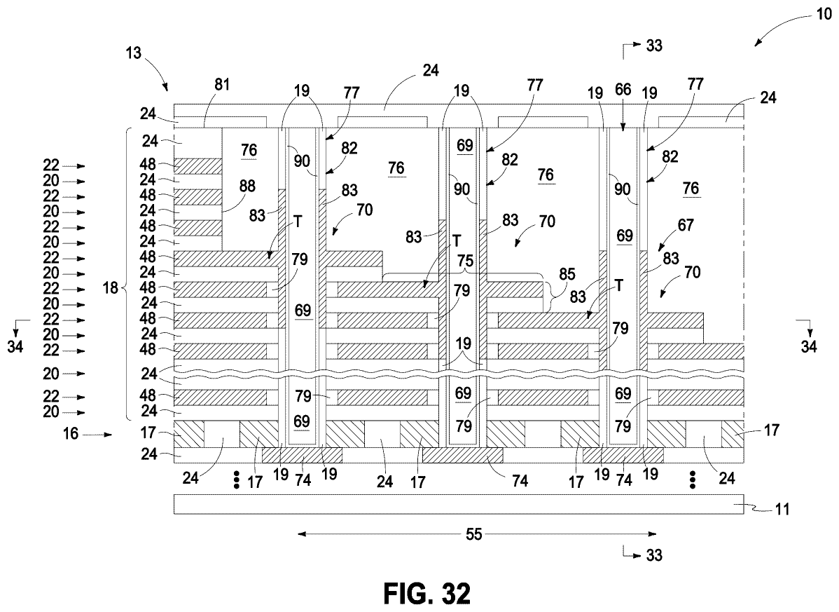

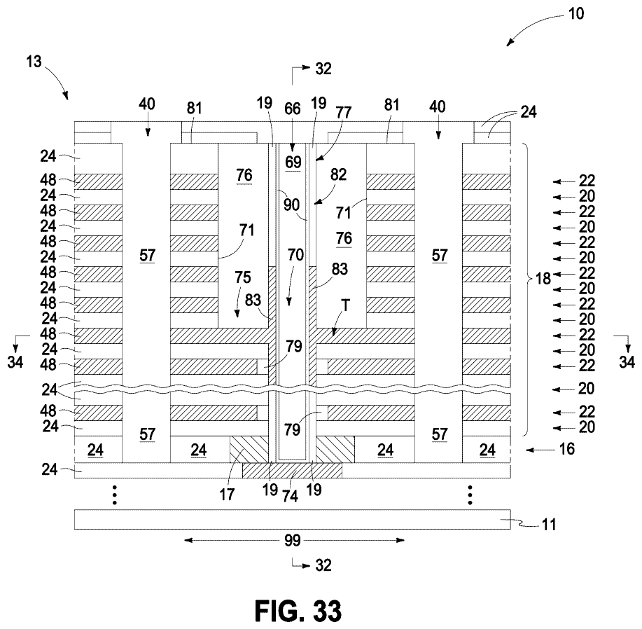

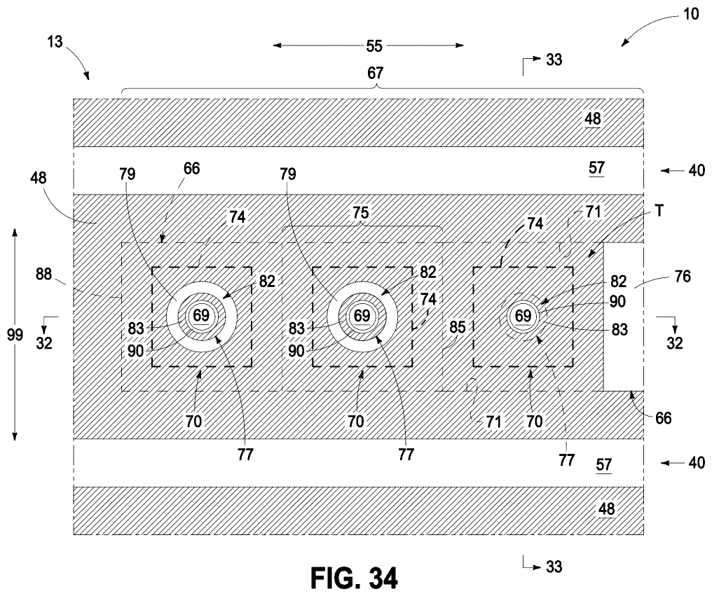

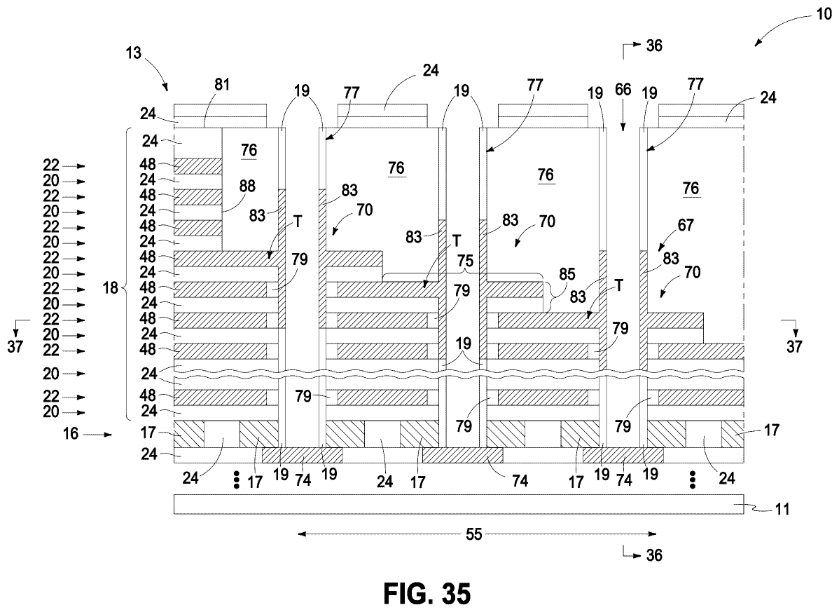

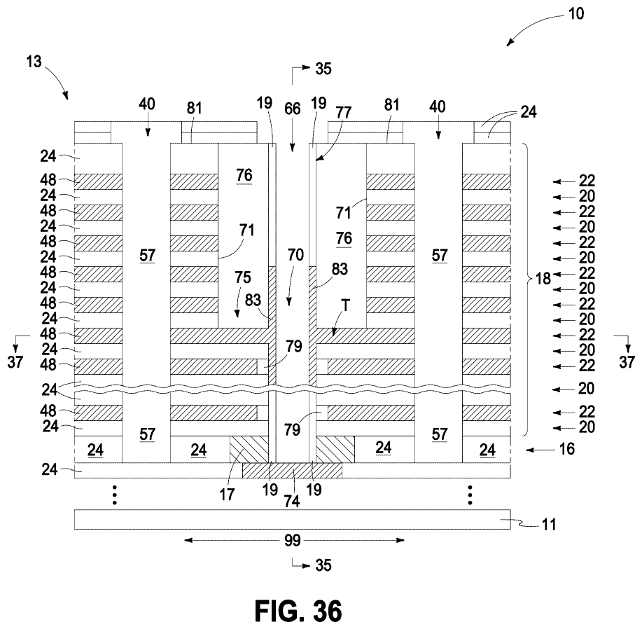

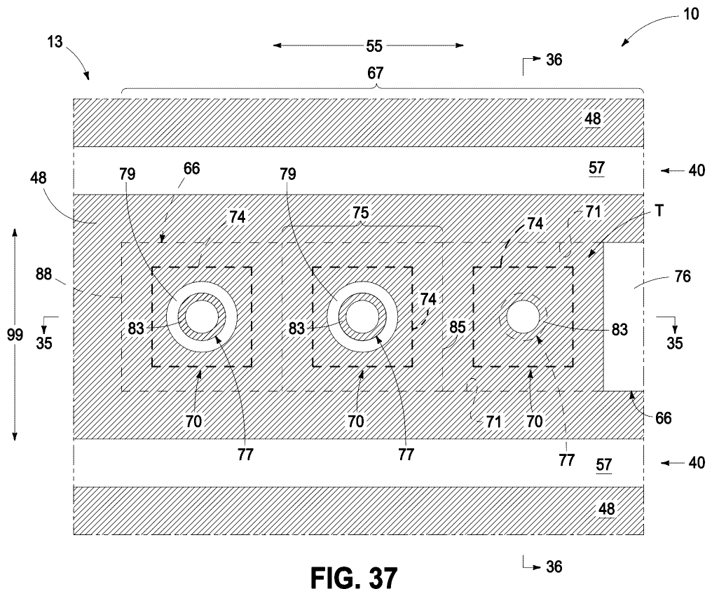

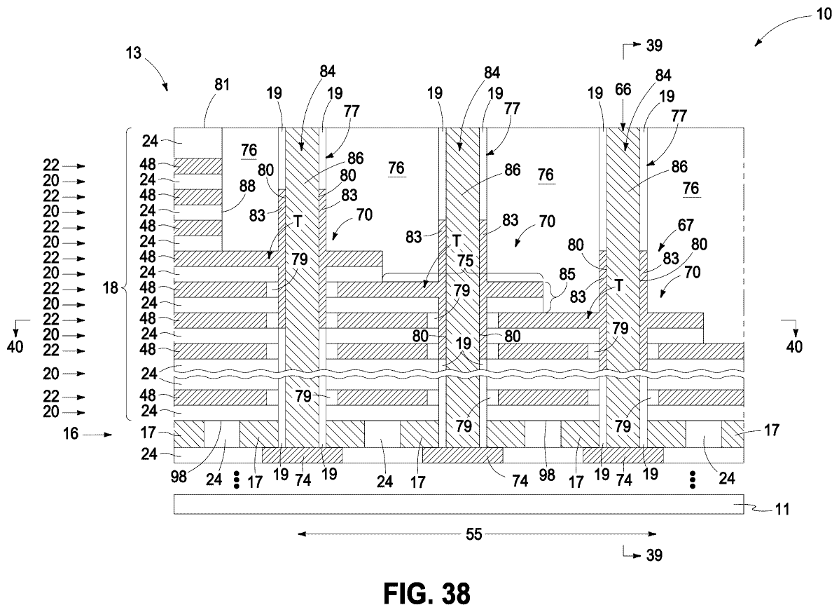

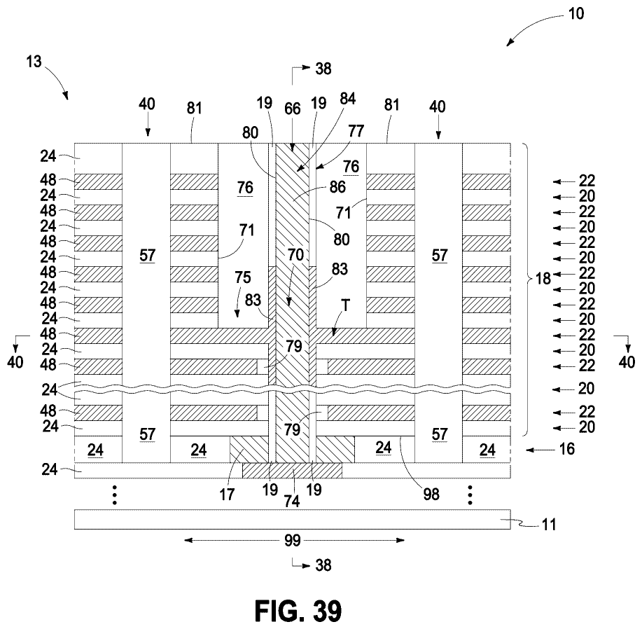

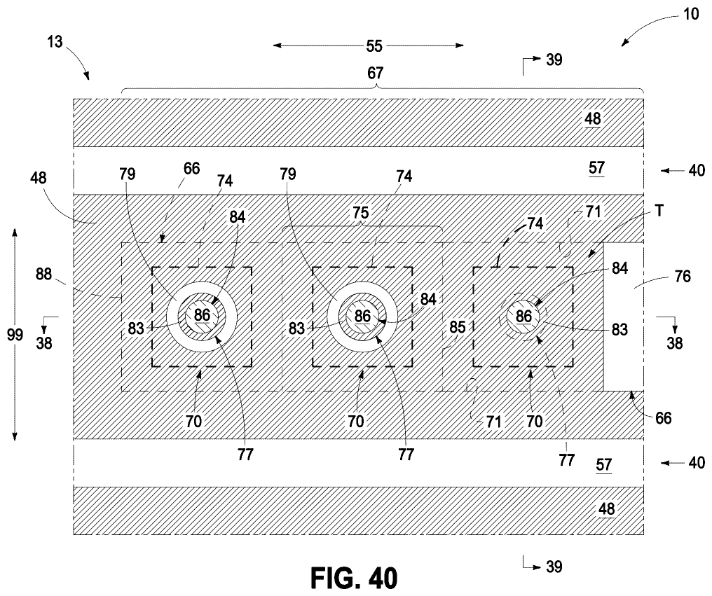

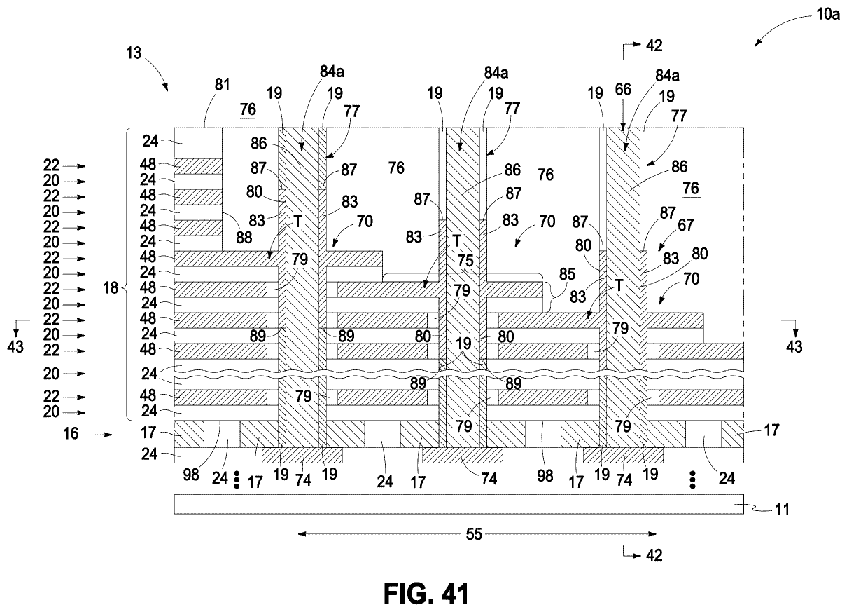

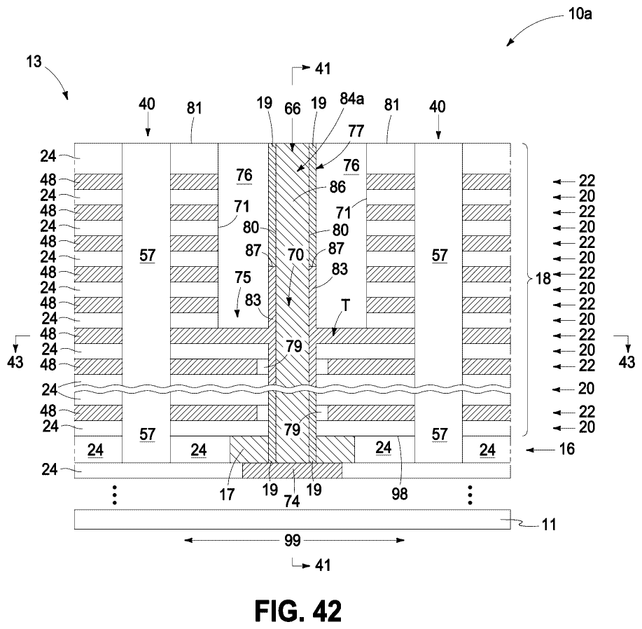

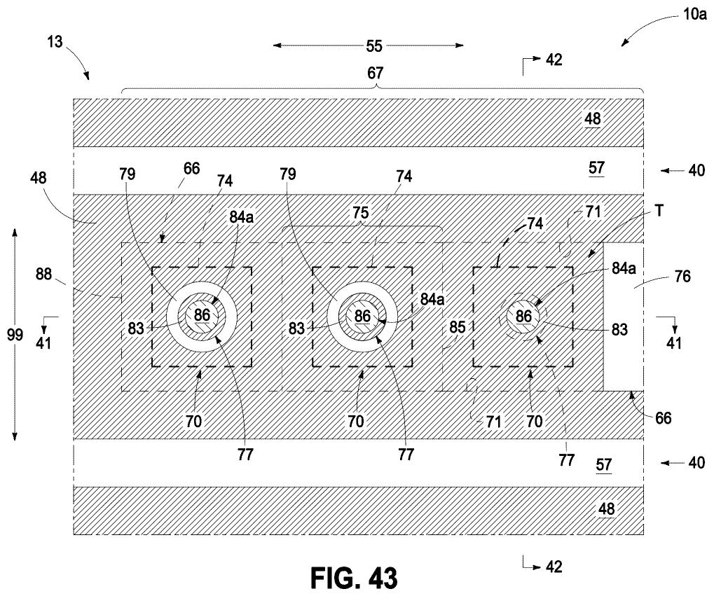

FIGS. 2 and 4-43 are diagrammatic sectional, expanded, enlarged, and/or partial views of the construction of FIGS. 1 and 3 or portions thereof, and/or of alternate embodiments.

### DETAILED DESCRIPTION OF EXAMPLE EMBODIMENTS

Embodiments of the invention encompass methods used in forming integrated circuitry, for example memory circuitry comprising a memory array, for example an array of NAND or other memory cells (e.g., integrated-circuitry components) that may have at least some peripheral control circuitry under the array (e.g., CMOS-under-array). Alternately, and by way of examples only, peripheral control circuitry may be above the array or to a side of the array. Embodiments of the invention encompass so-called “gate-last” or “replacement-gate” processing, so-called “gate-first” processing, and other processing whether existing or future-developed independent of when transistor gates are formed. Embodiments of the invention also encompass integrated circuitry such as that comprising a memory array comprising strings of memory cells (e.g., NAND architecture) independent of method of manufacture. Some example embodiments are described with reference to FIGS. 1-43.

In FIGS. 1-8, an example construction 10 has two memory-array regions 12 in which elevationally-extending strings of transistors and/or memory cells will be formed. The two memory-array regions 12 may be of the same construction or different constructions relative one another. In one embodiment, a stair-step region 13 is between memory-array regions 12 and comprises stair-step structures as described below. Alternately, by way of example, a stair-step region may be at the end of a single memory-array region (not shown). FIGS. 6-8 are of different and varying scales compared to FIGS. 1-5 for clarity in disclosure more pertinent to stair-step region 13 than to memory-array regions 12. Example construction 10 comprises a base substrate 11 having any one or more of conductive/conductor/conducting, semiconductive/semiconductor/semiconducting, or insulative/insulator/insulating (i.e., electrically herein) materials. Various materials have been formed elevationally over base substrate 11. Materials may be aside, elevationally inward, or elevationally outward of the FIGS. 1-8-depicted materials. For example, other partially or wholly fabricated components of integrated circuitry may be provided somewhere above, about, or within base substrate 11. Control and/or other peripheral circuitry for operating components within an array (e.g., individual array regions 12) of elevationally-extending strings of memory cells may also be fabricated and may or may not be wholly or partially within an array or sub-array. Further, multiple sub-arrays may also be fabricated and operated independently, in tandem, or otherwise relative one another. In this document, a “sub-array” may also be considered as an array.

A conductor tier 16 comprising conductor material 17 (e.g., WSiₓ under conductively-doped polysilicon) is above substrate 11. Conductor tier 16 may comprise part of control circuitry (e.g., peripheral-under-array circuitry and/or a common source line or plate) used to control read and write access to the transistors and/or memory cells in array 12. A vertical stack 18 comprising vertically-alternating insulative tiers 20 and conductive tiers 22 is directly above conductor tier 16 and extends from memory-array region(s) 12 into stair-step region 13 along a first direction 55. In some embodiments, conductive tiers 22 may be referred to as first tiers 22 and insulative tiers 20 may be referred to as second tiers 20, with first tiers 22 being conductive and second tiers 20 being insulative at least in a finished-circuitry construction. Example thickness for each of tiers 20 and 22 is 20 to 60 nanometers. The example uppermost tier 20 may be thicker/thickest compared to one or more other tiers 20 and/or 22. Example first tiers 22 comprise material 26 (in one embodiment at least predominantly comprising sacrificial material [e.g., silicon nitride] and in some embodiments referred to as first sacrificial material) and example second tiers 20 comprise an insulative material 24 (e.g., silicon dioxide). Only a small number of tiers 20 and 22 is shown in FIGS. 2-8 and other figures, with more likely stack 18 comprising dozens, a hundred or more, etc. of tiers 20 and 22. Other circuitry that may or may not be part of peripheral and/or control circuitry may be between conductor tier 16 and stack 18. For example, multiple vertically-alternating tiers of conductive material and insulative material of such circuitry may be below a lowest of the conductive tiers 22 and/or above an uppermost of the conductive tiers 22. For example, one or more select gate tiers (not shown) may be between conductor tier 16 and the lowest conductive tier 22 and one or more select gate tiers may be above an uppermost of conductive tiers 22 (not shown). Alternately or additionally, at least one of the depicted uppermost and lowest conductive tiers 22 may be a select gate tier. Circuitry may also be directly below stack 18, for example, an example conductive landing pad of such circuitry in insulative material 24 being designated with numeral 74 in FIGS. 6-8. Example such circuitry comprises CMOS-under-array circuitry or other control circuitry the specifics of which are not otherwise material to aspects of the invention.

Channel openings 25 have been formed (e.g., by etching) through insulative tiers 20 and conductive tiers 22 to conductor tier 16. Channel openings 25 may taper radially-inward and/or radially-outward (not shown) moving deeper in stack 18. In some embodiments, channel openings 25 may go into conductor material 17 of conductor tier 16 as shown or may stop there-atop (not shown). Alternately, as an example, channel openings 25 may stop atop or within the lowest insulative tier 20. A reason for extending channel openings 25 at least to conductor material 17 of conductor tier 16 is to assure direct electrical coupling of channel material to conductor tier 16 without using alternative processing and structure to do so when such a connection is desired and/or to provide an anchoring effect to material that is within channel openings 25. Etch-stop material (not shown) may be within or atop conductor material 17 of conductor tier 16 to facilitate stopping of the etching of channel openings 25 relative to conductor tier 16 when such is desired. Such etch-stop material may be sacrificial or non-sacrificial. By way of example and for brevity only, channel openings 25 are shown as being arranged in groups or columns of staggered rows of four and five openings 25 per row and being arrayed in laterally-spaced memory-block regions 58 that will comprise laterally-spaced memory blocks 58 in a finished circuitry construction. In this document, “block” is generic to include “sub-block”. Memory-block regions 58 and resultant memory blocks 58 (not yet shown) may be considered as being longitudinally elongated and oriented, for example along first direction 55, with a second direction 99 being orthogonal thereto. Any alternate existing or future-developed arrangement and construction may be used.

Transistor channel material may be formed in the individual channel openings elevationally along the insulative tiers and the conductive tiers, thus comprising individual channel-material strings, which is directly electrically coupled with conductive material in the conductor tier. Individual memory cells of the example memory array being formed may comprise a gate region (e.g., a control-gate region) and a memory structure laterally between the gate region and the channel material. In one such embodiment, the memory structure is formed to comprise a charge-blocking region, storage material (e.g., charge-storage material), and an insulative charge-passage material. The storage material (e.g., floating gate material such as doped or undoped silicon or charge-trapping material such as silicon nitride, metal dots, etc.) of the individual memory cells is elevationally along individual of the charge-blocking regions. The insulative charge-passage material (e.g., a band gap-engineered structure having nitrogen-containing material [e.g., silicon nitride] sandwiched between two insulator oxides [e.g., silicon dioxide]) is laterally between the channel material and the storage material.

The figures show one embodiment wherein charge-blocking material 30, storage material 32, and charge-passage material 34 have been formed in individual channel openings 25 elevationally along insulative tiers 20 and conductive tiers 22. Transistor materials 30, 32, and 34 (e.g., memory-cell materials) may be formed by, for example, deposition of respective thin layers thereof over stack 18 and within individual channel openings 25 followed by planarizing such back at least to a top surface of stack 18 as shown.

Channel material 36 has also been formed in channel openings 25 elevationally along insulative tiers 20 and conductive tiers 22 and comprise individual channel-material strings 53, in one embodiment, having memory-cell materials (e.g., 30, 32, and 34) there-along and with material 24 in insulative tiers 20 being horizontally-between immediately-adjacent channel-material strings 53. Materials 30, 32, 34, and 36 are collectively shown as and only designated as material 37 in some figures due to scale. Example channel materials 36 include appropriately-doped crystalline semiconductor material, such as one or more silicon, germanium, and so-called III/V semiconductor materials (e.g., GaAs, InP, GaP, and GaN). Example thickness for each of materials 30, 32, 34, and 36 is 25 to 100 Angstroms. Punch etching may be conducted as shown to remove materials 30, 32, and 34 from the bases of channel openings 25 to expose conductor tier 16 such that channel material 36 (channel-material string 53) is directly electrically coupled with conductor material 17 of conductor tier 16. Such punch etching may occur separately with respect to each of materials 30, 32, and 34 (as shown) or may occur collectively with respect to all after deposition of material 34 (not shown). Alternately, and by way of example only, no punch etching may be conducted and channel material 36 may be directly electrically coupled with conductor material 17 of conductor tier 16 by a separate conductive interconnect (not shown). Channel openings 25 are shown as comprising a radially-central solid dielectric material 38 (e.g., spin-on-dielectric, silicon dioxide, and/or silicon nitride). Alternately, and by way of example only, the radially-central portion within channel openings 25 may include void space(s) (not shown) and/or be devoid of solid material (not shown).

Referring to FIGS. 1 and 6-8, and in one embodiment, cavities 66 have been formed in stack 18 in stair-step region 13 and that individually comprise a stair-step structure as described below. Example cavities 66 are aligned longitudinally end-to-end in individual memory-block regions 58 and have a crest 81 between immediately-adjacent cavities 66 (e.g., cavities 66 being spaced relative one another in first direction 55 by crests 81). Alternately, only a single cavity may be in individual memory-block regions 58 (not shown). Nevertheless, some method and structure embodiments include fabrication of and a resultant construction having only a single cavity 66. Cavities 66 are shown as being rectangular in horizontal cross-section, although other shape(s) may be used and all need not be of the same shape relative one another. For brevity, less tiers 20 and 22 are shown in FIGS. 3 and 5 as compared to FIGS. 7 and 8, with more tiers 20 and 22 being shown in FIGS. 7 and 8 for clarity and for better emphasis of example processing/aspects associated with structures in example cavities 66.

Example cavities 66 individually comprise a flight 67 of stairs 70 extending along a first direction (e.g., 55). A mirror-image flight of stairs 70 (not shown) may be opposite flight 67, with a landing there-between (not shown), and together be considered as comprising a stair-step structure (e.g., at least initially defining a stadium appearing as a vertically recessed portion having opposing flights of stairs). Individual stairs 70 comprise a tread 75 and a riser 85. Individual treads 75 comprise a target first tier T that is one of first tiers 22. Cavities 66 with flight 67 and a mirror-image opposing flight may be formed by any existing or later-developed method(s). As one such example, a masking material (e.g., a photo-imageable material such as photoresist) may be formed atop stack 18 and an opening formed there-through. Then, the masking material may be used as a mask while etching (e.g., anisotropically) through the opening to extend such opening into at least two outermost two tiers 20, 22. The resultant construction may then be subjected to a successive alternating series of lateral-trimming etches of the masking material followed by etching deeper into stack 18, at least two tiers 20, 22 at a time, using the trimmed masking material having a successively widened opening as a mask. Such an example may result in the forming of flight 67 into stack 18 that comprises vertically alternating tiers 20, 22 of different composition materials 24, 26, and in the forming of another flight opposite flight 67 (again, not shown). Likely more stairs 70 will be in flight 67 than shown. Example stairs 70 in stack 18 are individually shown as comprising one first tier 22 and one second tier 20 (the order of which may be reversed and not shown). More first and second tiers per stair 70 may be used, for example if forming multiple treads per stair (e.g., along second direction 99 and not shown). Further, horizontal depth of treads 75 in direction 55 and vertical height of risers 85 may be equal or different relative one another. Flights 67 and an opposing flight may be translated (etched) deeper into stack 18 together and/or while one of flights 67 or an opposing flight is masked depending on the circuitry being fabricated.

Opposing flights (e.g., stadiums) may be formed in multiple cavities 66, for example longitudinally end-to-end as shown and to different depths within stack 18 for accessing different first/conductive tiers 22 throughout stack 18. Further, one of the opposing flights of stairs in individual ones of the stadiums may be separately translated deeper into stack 18 for accessing different first/conductive tiers 22 throughout the stack. Regardless, cavities 66 may be formed before or after forming channel-material strings 53. Cavities 66 may be considered as having laterally-outermost sidewalls 71 (relative to second direction 99) and 88 (relative to first direction 55), with risers 85 that are part of individual stairs 70 along with sidewalls 88 effectively being part of the sidewalls of cavities 66 that are along second direction 99, with sidewalls 71 being along first direction 55. Sidewalls 71, 88 and/or the risers may taper laterally-inward or outward moving deeper into stack 18 (not shown). An insulative material 76 (e.g., silicon dioxide) is within cavities 66.

Example treads 75 and risers 85 in one embodiment individually comprise sacrifice material 64 atop insulative material 24, the order of which may be reversed. Sacrifice material 64, when used, is of different composition from that of sacrificial material 26 (e.g., such that each has different etch characteristics relative to the other). When used, sacrifice material 64 may be formed by inserting a substance (e.g., by ion implanting) into sacrificial material 26 of treads 75. For example, and by way of example only, where sacrificial material 26 is stoichiometric silicon nitride, an example substance is atomic carbon to form a silicon carbonitride material whereby material 26 can be etched selectively relative to material 64 using phosphoric acid or HF. Alternately, as examples only, boron and/or arsenic may be used. Only processing associated with a single tread 75 is largely referred to below for clarity, with it being recognized that such processing and resultant structures will likely occur with respect to multiple treads.

Referring to FIGS. 9-14, an opening 77 has been formed in tread 75 downwardly through target first tier T and vertically-alternating first and second tiers 22, 20 that are directly there-below (e.g., and through sacrifice material 64 when present). Opening 77 may extend to material that is directly below stack 18 as shown (e.g., to material 24 and 74 in the depicted example). Horizontally-elongated trenches 40 have also been formed (e.g., by anisotropic etching using a common mask to form openings 77 and 40) between immediately-laterally-adjacent memory-block regions 58. Trenches 40 will typically be wider than channel openings 25 (e.g., 3 to 10 times wider). Trenches 40 may have respective bottoms that are directly against conductor material 17 (e.g., atop or within) of conductor tier 16 (as shown) or may have respective bottoms that are above conductor material 17 of conductor tier 16 (not shown). Opening 77 and trenches 40 may taper laterally inward and/or outward in vertical cross-section (not shown). Sacrificial material 69 has been formed in opening 77 and trenches 40 (e.g., polysilicon, carbon, or metal material [regardless of conductive properties]). A protective insulative material (e.g., 24) may subsequently be formed thereover as shown.

Referring to FIGS. 15-17, and in one embodiment, protective insulative material 24 has been removed from being over opening 77, while remaining over trenches 40, and sacrificial material 69 has been removed from opening 77. Thereafter, sacrificial material 26 in first tiers 22 that is below target first tier T of tread 75 has been radially recessed (e.g., by selective isotropic etching) relative to insulative material 24, insulative material 76, and sacrifice material 64 (when present) (e.g., using hot phosphoric acid when sacrificial material 26 is silicon nitride and sacrifice material 64 is present and comprises carbon-doped silicon nitride or silicon carbonitride). Such may round the ends of insulative material 24 exposed to opening 77 in second tiers 20 that are below target first tier T of tread 75 (not shown). An insulative material (e.g., silicon dioxide) may be deposited to line opening 77 and fill such radial recesses, followed by isotropically etching such insulative material back at least to original sidewalls of opening 77 and to expose sacrifice material 64 (when present), and thereby form insulative rings 79. Such is but one example of forming an insulative ring 79 circumferentially around opening 77 in individual of first tiers 22 that are directly below target first tier T of tread 75 that comprises sacrifice material 64. Insulative rings 79 are of different composition from compositions of sacrificial material 26 and sacrifice material 64.

Referring to FIGS. 18-20, and in some embodiments, a liner 19 has been formed to line and less than fill opening 77. Such may be anisotropically etched as shown to substantially remove such from being over horizontal surfaces as shown. In method embodiments, liner 19 is referred to as radially-outer liner 19. Liner 19 may be insulative (e.g., silicon nitride), semiconductive (doped or undoped semiconductive material), or conductive (e.g., conductive metal material). An optional sacrificial lining 90 (e.g., silicon dioxide) has then been formed in opening 77 over liner 19, followed by filling of remaining volume of opening 77 with more sacrificial material 69. A protective insulative material (e.g., 24) may subsequently be formed thereover as shown.

The processing shown by FIGS. 9-20 is but one example of forming a structure 82 (e.g., received in opening 77) vertically through tread 75 and that extends from directly above target first tier T, through target first tier T, and directly below target first tier T to material that is directly below stack 18 (e.g., to material 17 and 74 in the depicted example). Structure 82 comprises radially-outer liner 19 that extends elevationally there-along through multiple of first and second tiers 22, 20 including through target first tier T. In one embodiment, structure 82 but for radially-outer liner 19 is sacrificial as described below. Alternately, structure 82 may not be sacrificial (e.g., comprising a conductive via construction at this point of processing [not shown] and in a finished circuitry construction.

Referring to FIGS. 21-25, trenches 40 have been exposed through protective insulative material 24 while structure 82 remains covered thereby. This has been followed by etching sacrificial material 26 (no longer shown) selectively relative to insulative material 24 and exposing radially-outer liner 19 that is in target first tier T of tread 75. In one embodiment where sacrifice material 64 is present (no longer shown), sacrificial material 26 is etched selectively relative to such sacrifice material 64 and insulative ring 79 (when present; e.g., using phosphoric acid), followed by etching such sacrifice material 64 (when present and no longer shown; e.g., conducting a vapor etch using a F-containing precursor [e.g., NF₃, SF₆, HF, etc.]H₂, and O if sacrifice material 64 is carbon-doped silicon nitride or silicon carbonitride). Further, and regardless, exposed radially-outer liner 19 is etched upwardly and downwardly from target first tier T of tread 75 to form a void-space 83 that extends upwardly and downwardly from target first tier T of tread 75. Etching chemistry(ies) used to form void-space 83 will depend on composition of radially-outer liner 19 as will be appreciated by the artisan. Optional sacrificial lining 90 may be present to preclude etching/attack of sacrificial material 69 during such etching if desired.

Referring to FIGS. 26-34, conductive material 48 (e.g., conductive metal material) has been formed in first tiers 22 (e.g., through trenches 40) and in void-space 83 to extend upwardly and downwardly from target first tier T of tread 75. In one embodiment, conductive material 48 that is in target first tier T of tread 75 extends upwardly and downwardly from target first tier T of tread 75 through multiple of first tiers 22 that are above and below target first tier T of tread 75. In one embodiment, conductive material 48 that is in target first tier T of tread 75 extends upwardly and downwardly from target first tier T of tread 75 the same amounts, thus forming a sideways T-shape of conductive material 48 in a vertical cross-section (e.g., the vertical cross-section that is FIG. 32). Conductive material 48 has also been formed in first tiers 22 in array region 12 and extends from array region 12 into stair-step region 13. Conductive material 48 has thereafter been removed from trenches 40, thus forming individual conductive lines 29 (e.g., wordlines) in stack 18 and elevationally-extending strings 49 of individual transistors and/or memory cells 56 in stack 18. In one embodiment, after removing sacrificial materials 26 and prior to the forming conductive material 48, first tiers 22 may be lined with an insulating material (e.g., AlO_{X} and not shown), with conductive material 48 being formed thereover.

Approximate locations of transistors and/or memory cells 56 are indicated with a bracket in some figures and some with dashed outlines in some figures, with transistors and/or memory cells 56 being essentially ring-like or annular in the depicted example. Alternately, transistors and/or memory cells 56 may not be completely encircling relative to individual channel openings 25 such that each channel opening 25 may have two or more elevationally-extending strings 49 (e.g., multiple transistors and/or memory cells about individual channel openings in individual conductive tiers with perhaps multiple wordlines per channel opening in individual conductive tiers, and not shown). Conductive material 48 may be considered as having terminal ends 50 corresponding to control-gate regions 52 of individual transistors and/or memory cells 56. Control-gate regions 52 in the depicted embodiment comprise individual portions of individual conductive lines 29. Materials 30, 32, and 34 may be considered as a memory structure 65 that is laterally between control-gate region 52 and channel material 36. In one embodiment and as shown with respect to the example “gate-last” processing, conductive material 48 of conductive tiers 22 is formed after forming channel openings 25 and/or trenches 40. Alternately, the conductive material of the conductive tiers may be formed before forming channel openings 25 and/or trenches 40 (not shown), for example with respect to “gate-first” processing.

A charge-blocking region (e.g., charge-blocking material 30) is between storage material 32 and individual control-gate regions 52. A charge block may have the following functions in a memory cell: In a program mode, the charge block may prevent charge carriers from passing out of the storage material (e.g., floating-gate material, charge-trapping material, etc.) toward the control gate, and in an erase mode the charge block may prevent charge carriers from flowing into the storage material from the control gate. Accordingly, a charge block may function to block charge migration between the control-gate region and the storage material of individual memory cells. An example charge-blocking region as shown comprises insulator material 30. By way of further examples, a charge-blocking region may comprise a laterally (e.g., radially) outer portion of the storage material (e.g., material 32) where such storage material is insulative (e.g., in the absence of any different-composition material between an insulative storage material 32 and conductive material 48). Regardless, as an additional example, an interface of a storage material and conductive material of a control gate may be sufficient to function as a charge-blocking region in the absence of any separate-composition-insulator material 30. Further, an interface of conductive material 48 with material 30 (when present) in combination with insulator material 30 may together function as a charge-blocking region, and as alternately or additionally may a laterally-outer region of an insulative storage material (e.g., a silicon nitride material 32). An example material 30 is one or more of silicon hafnium oxide and silicon dioxide.

Intervening material 57 has been formed in trenches 40 and thereby laterally-between and longitudinally-along immediately-laterally-adjacent memory blocks 58. Intervening material 57 may provide lateral electrical isolation (insulation) between immediately-laterally-adjacent memory blocks. Such may include one or more of insulative, semiconductive, and conducting materials and, regardless, may facilitate conductive tiers 22 from shorting relative one another in a finished circuitry construction. Example insulative materials are one or more of SiO₂, Si₃N₄, and Al₂O₃. Intervening material 57 may include through-array-vias (not shown).

One or more separate select-gate-drain tiers (not shown) could be formed atop stack 18 and separated into sub-blocks (not shown) at this point in processing or one or more uppermost conductive tiers 22 of stack 18 could be select-gate-drain tiers and so processed (not shown).

Referring to FIGS. 35-37, access holes have been formed through protective insulative material 24 to structures 82 (no longer so-designated). Thereafter, sacrificial material 69 (no longer shown) has been exhumed (e.g., using tetramethyl ammonium hydroxide if polysilicon or ashing with oxygen if carbon), followed by exhuming sacrificial lining 90 (if present, and no longer shown). Thereby, conductive material 48 will be exposed in opening 77, or the insulative lining (e.g., AlOₓ) referred to above and not shown if used will be exposed in opening 77. If so used, such would be etched at this point of processing to expose conductive material 48 to opening 77. Regardless, and in one embodiment, such processing is an example of removing structure 82 (no longer shown/designated) but for radially-outer liner 19 after forming conductive material 48.

Referring to FIGS. 38-40, and in one embodiment, a conductive via 84 has been formed to replace structure 82 but for its liner 19, with conductive via 84 extending from directly above, through, and to directly below target first tier T of tread 75 to material that is directly below stack 18 (e.g., to material 24 and 74 in the depicted example). Conductive via 84 comprises conductor material 86 that is directly against conductive material 48 that is in target first tier T of tread 75 and directly against conductive material 48 that is in void-space 83. In one embodiment and as shown, conductive material 48 that extends upwardly and downwardly in void-space 83 completely circumferentially surrounds conductor material 86 of conductive via 84. In one embodiment, radially-outer liner 19 is radially between conductor material 86 of conductive via 84 and insulative ring 79.

As stated above, radially-outer liner 19 may be insulative, semiconductive, or conductive. FIGS. 41-43 show an alternate construction 10a wherein radially-outer liner 19 is hatched to indicate such is conductive (e.g., comprising conductive metal material) and thereby comprises part of conductive via 84a. Like numerals from the above-described embodiment have been used where appropriate, with some construction differences being indicated with the suffix “a” or with different numerals.

Any other attribute(s) or aspect(s) as shown and/or described herein with respect to other embodiments may be used in the embodiments shown and described with reference to the above embodiments.

Alternate embodiment constructions may result from method embodiments described above, or otherwise. Regardless, embodiments of the invention encompass memory arrays independent of method of manufacture. Nevertheless, such memory arrays may have any of the attributes as described herein in method embodiments. Likewise, the above-described method embodiments may incorporate, form, and/or have any of the attributes described with respect to device embodiments.

In one embodiment, integrated circuitry (e.g., 10, 10a) comprises a stack (e.g., 18) comprising vertically-alternating insulative tiers (e.g., 20) and conductive tiers (e.g., 22) that extend from an array region (e.g., 12) into a stair-step region (e.g., 13). The stair-step region comprises a flight (e.g., 67) of stairs (e.g., 70) that comprise treads (e.g., 75). Individual of the treads comprise a target conductive tier (e.g., T) that is one of the conductive tiers. A conductive via (e.g., 84, 84a) extends from directly above, through, and to directly below one of the individual treads to a bottom (e.g., 98) of the stack. The conductive via comprises conductor material (e.g., 86) that is directly electrically coupled to conductive material (e.g., 48) that is in the target conductive tier of the one individual tread. The conductive material that is in the target conductive tier of the one individual tread extends upwardly and downwardly from the target conductive tier of the one individual tread and is aside and directly against sidewalls (e.g., 80) of the conductor material of the conductive via directly above and directly below the target conductive tier of the one individual tread.

In one embodiment, the conductor material and the conductive material are of different compositions relative one another and in another embodiment are of the same composition relative one another. In one embodiment, the conductive material that extends upwardly and downwardly completely circumferentially surrounds the conductor material of the conductive via. In one embodiment, the conductive material that is in the target conductive tier of the one individual tread extends upwardly and downwardly from the target conductive tier of the one individual tread the same amount, thus forming a sideways T-shape of the conductive material in a vertical cross-section (e.g., that of FIG. 38 or FIG. 41). In one embodiment, the conductive material that is in the target conductive tier of the one individual tread extends upwardly and downwardly from the target conductive tier of the one individual tread through multiple of the conductive tiers that are above and below the target conductive tier of the one individual tread.

In one embodiment, the integrated circuitry comprises memory circuitry and the array region comprises an array of memory cells (e.g., 56) comprising channel-material strings (e.g., 53) extending through the stack in the array region.

In one embodiment, the integrated circuitry comprises a liner (e.g., 19) that is completely circumferentially surrounding about the conductive via, with the liner being at least partially directly above and at least partially directly below the conductive material that extends upwardly and downwardly from the target conductive tier of the one individual tread. In one such embodiment, the liner is insulative.

Any other attribute(s) or aspect(s) as shown and/or described herein with respect to other embodiments may be used.

In one embodiment, integrated circuitry (e.g., 10a) comprises a stack (e.g., 18) comprising vertically-alternating insulative tiers (e.g., 20) and conductive tiers (e.g., 22) that extend from an array region (e.g., 12) into a stair-step region (e.g., 13). The stair-step region comprises a flight (e.g., 67) of stairs (e.g., 70) that comprise treads (e.g., 75). Individual of the treads comprise a target conductive tier (e.g., T) that is one of the conductive tiers. A conductive via (e.g., 84a) extends from directly above, through, and to directly below one of the individual treads to a bottom (e.g., 98) of the stack. The conductive via comprises conductor material (e.g., 86) that is directly electrically coupled to conductive material (e.g., 48) that is in the target conductive tier of the one individual tread. The conductive via comprise radially-inner conductor material (e.g., 86) and radially-outer conductor material (e.g., liner 19 being conductive in this embodiment, thus the material thereof comprising such radially-outer conductor material) that are directly against one another directly above and directly below the target conductive tier of the one individual tread. The conductive material that is in the target conductive tier of the one individual tread extends upwardly and downwardly from the target conductive tier of the one individual tread and is aside and directly against sidewalls (e.g., 80) of the radially-inner conductor material of the conductive via directly above and directly below the target conductive tier of the one individual tread. The radially-outer conductor material of the conductive via is directly against a top (e.g., 87) of the conductive material that extends upwardly from the target conductive tier of the one individual tread. The radially-outer conductor material of the conductive via is directly against a bottom (e.g., 89) of the conductive material that extends downwardly from the target conductive tier of the one individual tread.

In one embodiment, the radially-inner conductor material and the radially-outer conductor material are of different compositions relative one another and in another embodiment are of the same composition relative one another. In one embodiment, the conductive material is of different composition from at least one of the radially-inner conductor material and the radially-outer conductor material. In one embodiment, the conductive material is of the same composition as that of at least one of the radially-inner conductor material and the radially-outer conductor material.

Any other attribute(s) or aspect(s) as shown and/or described herein with respect to other embodiments may be used.

Embodiments of the invention may provide a greater connection area of conductive material of the target tier with the conductive via than prior constructions, thereby reducing wordline/access line resistance. Further, breakdown voltage risk between wordlines/access lines and contacts may be reduced by providing another insulator layer (e.g., 19 when used and when insulative) between the conductive via and all other wordlines/access lines than where cross-part of the sideways T-shape covers the wordlines/access lines.

The memory circuitry described herein (e.g., the conductive vias thereof) may connect with circuitry that is on either the top or the bottom (i.e., either z-axis side) of the stack regardless of orientation of the construction in three-dimensional space and which is not material to aspects of the inventions disclosed herein. For example, and by way of example only, the conductive vias may connect with peripheral control circuitry that is beneath the stack with respect to the orientation shown in the drawings. As an alternate example, and by way of example only, the conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, source lines or plates may be fabricated relative to the bottom of the stack with respect to the shown orientation but inverted therefrom during processing. Such source lines or plates may connect with conductive vias that extend through the stack to the substrate bonded with the other side that has such peripheral control circuitry. Regardless, constructions as shown and described herein may be processed, packaged, and/or mounted in any three-dimensional spatial orientation.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication and as shown in drawings (if any) herein, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, a method used in forming integrated circuitry comprises forming a stack comprising vertically-alternating first tiers and second tiers that extend from an array region into a stair-step region. The first tiers comprise sacrificial material and the second tiers comprise insulative material. The stair-step region comprises a flight of stairs. The stairs individually comprising a tread comprising a target first tier that is one of the first tiers. A structure is formed vertically through the tread and that extends from directly above the target first tier, through the target first tier, and directly below the target first tier to material that is directly below the stack. The structure comprises a radially-outer liner that extends elevationally there-along through multiple of the first and second tiers including through the target first tier. The sacrificial material is etched selectively relative to the insulative material and the radially-outer liner that is in the target first tier of the tread is exposed. The exposed radially-outer liner is etched upwardly and downwardly from the target first tier of the tread to form a void-space that extends upwardly and downwardly from the target first tier of the tread. Conductive material is formed in the first tiers and in the void-space to extend upwardly and downwardly from the target first tier of the tread.

In some embodiments, integrated circuitry comprises a stack comprising vertically-alternating insulative tiers and conductive tiers that extend from an array region into a stair-step region. The stair-step region comprises a flight of stairs that comprise treads. Individual of the treads comprise a target conductive tier that is one of the conductive tiers. A conductive via extends from directly above, through, and to directly below one of the individual treads to a bottom of the stack. The conductive via comprises conductor material that is directly electrically coupled to conductive material that is in the target conductive tier of the one individual tread. The conductive material that is in the target conductive tier of the one individual tread extends upwardly and downwardly from the target conductive tier of the one individual tread and is aside and directly against sidewalls of the conductor material of the conductive via directly above and directly below the target conductive tier of the one individual tread.

In some embodiments, integrated circuitry comprises a stack comprising vertically-alternating insulative tiers and conductive tiers that extend from an array region into a stair-step region. The stair-step region comprises a flight of stairs that comprise treads. Individual of the treads comprise a target conductive tier that is one of the conductive tiers. A conductive via extends from directly above, through, and to directly below one of the individual treads to a bottom of the stack. The conductive via is directly electrically coupled to conductive material that is in the target conductive tier of the one individual tread. The conductive via comprises radially-inner conductor material and radially-outer conductor material that are directly against one another directly above and directly below the target conductive tier of the one individual tread. The conductive material that is in the target conductive tier of the one individual tread extends upwardly and downwardly from the target conductive tier of the one individual tread and is aside and directly against sidewalls of the radially-inner conductor material of the conductive via directly above and directly below the target conductive tier of the one individual tread. The radially-outer conductor material of the conductive via is directly against a top of the conductive material that extends upwardly from the target conductive tier of the one individual tread. The radially-outer conductor material of the conductive via is directly against a bottom of the conductive material that extends downwardly from the target conductive tier of the one individual tread.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming integrated circuitry, comprising:
forming a stack comprising vertically-alternating first tiers and second tiers that extend from an array region into a stair-step region, the first tiers comprising sacrificial material and the second tiers comprising insulative material, the stair-step region comprising a flight of stairs, the stairs individually comprising a tread comprising a target first tier that is one of the first tiers;
forming a structure vertically through the tread and that extends from directly above the target first tier, through the target first tier, and directly below the target first tier to material that is directly below the stack; the structure comprising a radially-outer liner that extends elevationally there-along through multiple of the first and second tiers including through the target first tier;
etching the sacrificial material selectively relative to the insulative material and exposing the radially-outer liner that is in the target first tier of the tread;
etching the exposed radially-outer liner upwardly and downwardly from the target first tier of the tread to form a void-space that extends upwardly and downwardly from the target first tier of the tread; and
forming conductive material in the first tiers and in the void-space to extend upwardly and downwardly from the target first tier of the tread.

2. The method of claim 1 wherein the conductive material that is in the target first tier of the tread extends upwardly and downwardly from the target first tier of the tread through multiple of the first tiers that are above and below the target first tier of the tread.

3. The method of claim 1 wherein the conductive material that is in the target first tier of the tread extends upwardly and downwardly from the target first tier of the tread the same amounts thus forming a sideways T-shape of the conductive material in a vertical cross-section.

4. The method of claim 1 wherein,
the structure but for the radially-outer liner is sacrificial;
after forming the conductive material, removing the structure but for the radially-outer liner; and
after removing the structure but for the radially-outer liner, replacing it with a conductive via that extends from directly above, through, and to directly below the target first tier of the tread to the material that is directly below the stack, the conductive via comprising conductor material that is directly against the conductive material that is in the target first tier of the tread and directly against the conductive material that is in the void-space.

5. The method of claim 4 wherein the conductive material that extends upwardly and downwardly in the void-space completely circumferentially surrounds the conductor material of the conductive via.

6. The method of claim 4 wherein the radially-outer liner is insulative.

7. The method of claim 4 wherein the radially-outer liner is semiconductive.

8. The method of claim 4 wherein the radially-outer liner is conductive.

9. The method of claim 1 comprising:
before forming the structure, inserting a substance into the sacrificial material of the target first tier of the tread to form sacrifice material therefrom that is of different composition from that of the sacrificial material;
before forming the structure, forming an opening in the tread downwardly through the sacrifice material and the vertically-alternating first and second tiers directly there-below and in which the structure will be received;
forming an insulative ring circumferentially around the opening in individual of the first tiers that are directly below the target first tier of the tread that comprises the sacrifice material, the insulative ring being of different composition from compositions of the sacrificial and sacrifice materials;
the etching of the sacrificial material being conducted selectively relative to the sacrifice material and the insulating ring; and
after the etching of the sacrificial material, etching the sacrifice material and exposing the radially-outer liner that is in the target first tier of the tread.

10. The method of claim 9 wherein,
the structure but for the radially-outer liner is sacrificial;
after forming the conductive material, removing the structure but for the radially-outer liner;
after removing the structure but for the radially-outer liner, replacing it with a conductive via that extends from directly above, through, and to directly below the target first tier of the tread to the material that is directly below the stack, the conductive via comprising conductor material that is directly against the conductive material that is in the target first tier of the one individual tread and directly against the conductive material that is in the void-space.

11. The method of claim 10 wherein the radially-outer liner is radially between the conductor material of the conductive via and the insulative ring.

12. Integrated circuitry comprising:
a stack comprising vertically-alternating insulative tiers and conductive tiers that extend from an array region into a stair-step region, the stair-step region comprising a flight of stairs that comprise treads, individual of the treads comprising a target conductive tier that is one of the conductive tiers; and
a conductive via extending from directly above, through, and to directly below one of the individual treads to a bottom of the stack; the conductive via comprising conductor material that is directly electrically coupled to conductive material that is in the target conductive tier of the one individual tread, the conductive material that is in the target conductive tier of the one individual tread extending upwardly and downwardly from the target conductive tier of the one individual tread and being aside and directly against sidewalls of the conductor material of the conductive via directly above and directly below the target conductive tier of the one individual tread.

13. The integrated circuitry of claim 12 wherein the conductor material and the conductive material are of different compositions relative one another.

14. The integrated circuitry of claim 12 wherein the conductor material and the conductive material are of the same composition relative one another.

15. The integrated circuitry of claim 12 wherein the conductive material that extends upwardly and downwardly completely circumferentially surrounds the conductor material of the conductive via.

16. The integrated circuitry of claim 12 wherein the conductive material that is in the target conductive tier of the one individual tread extends upwardly and downwardly from the target conductive tier of the one individual tread the same amounts thus forming a sideways T-shape of the conductive material in a vertical cross-section.

17. The integrated circuitry of claim 12 wherein the conductive material that is in the target conductive tier of the one individual tread extends upwardly and downwardly from the target conductive tier of the one individual tread through multiple of the conductive tiers that are above and below the target conductive tier of the one individual tread.

18. The integrated circuitry of claim 12 comprising a liner that is completely circumferentially surrounding about the conductive via, the liner being at least partially directly above and at least partially directly below the conductive material that extends upwardly and downwardly from the target conductive tier of the one individual tread.

19. The integrated circuitry of claim 18 wherein the liner is insulative.

20. The integrated circuitry of claim 18 wherein the liner is semiconductive.

21. The integrated circuitry of claim 18 wherein the liner is conductive.

22. The integrated circuitry of claim 18 wherein the integrated circuitry comprises memory circuitry and the array region comprises an array of memory cells comprising channel-material strings extending through the stack in the array region.

23. Integrated circuitry comprising:
a stack comprising vertically-alternating insulative tiers and conductive tiers that extend from an array region into a stair-step region, the stair-step region comprising a flight of stairs that comprise treads, individual of the treads comprising a target conductive tier that is one of the conductive tiers; and
a conductive via extending from directly above, through, and to directly below one of the individual treads to a bottom of the stack; the conductive via being directly electrically coupled to conductive material that is in the target conductive tier of the one individual tread, the conductive via comprising radially-inner conductor material and radially-outer conductor material that are directly against one another directly above and directly below the target conductive tier of the one individual tread, the conductive material that is in the target conductive tier of the one individual tread extending upwardly and downwardly from the target conductive tier of the one individual tread and being aside and directly against sidewalls of the radially-inner conductor material of the conductive via directly above and directly below the target conductive tier of the one individual tread, the radially-outer conductor material of the conductive via being directly against a top of the conductive material that extends upwardly from the target conductive tier of the one individual tread, the radially-outer conductor material of the conductive via being directly against a bottom of the conductive material that extends downwardly from the target conductive tier of the one individual tread.

24. The integrated circuitry of claim 23 wherein the radially-inner conductor material and the radially-outer conductor material are of different compositions relative one another.

25. The integrated circuitry of claim 23 wherein the radially-inner conductor material and the radially-outer conductor material are of the same composition relative one another.

26. The integrated circuitry of claim 23 wherein the conductive material is of different composition from at least one of the radially-inner conductor material and the radially-outer conductor material.

27. The integrated circuitry of claim 23 wherein the conductive material is of the same composition as that of at least one of the radially-inner conductor material and the radially-outer conductor material.

28. The integrated circuitry of claim 23 wherein the integrated circuitry comprises memory circuitry and the array region comprises an array of memory cells comprising channel-material strings extending through the stack in the array region.
